(19) United States
(12) Patent Application Publication
(10) Pub. No.: US 2024/0141476 A1
(43) Pub. Date: May 2, 2024

(54) METHOD FOR MANUFACTURING A TARGET MATERIAL

(71) Applicant: TAIWAN STEEL GROUP AEROSPACE ADDITIVE MANUFACTURING CORPORATION, Tainan City (TW)

(72) Inventors: William HSIEH, Tainan City (TW); Bo-Chen Wu, Tainan City (TW); Chii-Feng Huang, Tainan City (TW); Jun-Cheng Wang, Tainan City (TW)

(73) Assignee: TAIWAN STEEL GROUP AEROSPACE ADDITIVE MANUFACTURING CORPORATION, Tainan City (TW)

(21) Appl. No.: 18/089,245

(22) Filed: Dec. 27, 2022

(30) Foreign Application Priority Data
Oct. 26, 2022 (TW) 111140687

(51) Int. Cl. C23C 14/34; B22F 10/28; B22F 10/64; B33Y 10/00; B33Y 40/20; B33Y 80/00; C22C 33/02

(52) U.S. Cl. CPC C23C 14/3407; B22F 10/28; B22F 10/64; B33Y 10/00; B33Y 40/20; B33Y 80/00; C22C 33/02; B22F 2201/02; B22F 2201/10; B22F 2304/10; C22C 38/32

(57) ABSTRACT

A method for manufacturing a target material is provided, including the steps of: disposing raw material powder on a substrate and melting the raw material powder by laser to form a target material layer; repeating the preceding process to allow a plurality of target material layers to form an integrated target material column; after cooling the target material column, removing the target material column from the substrate; and performing vacuum heat treatment on the target material column. Since the target material is additively manufactured and subjected to vacuum heat treatment, the target material has a finer and more uniform microstructure, thus improving the product quality.

### BACKGROUND

### 1. Technical Field

The present disclosure relates to manufacture of a target material, and more particularly to a method for manufacturing a target material in combination with additive manufacturing and post-treatment.

### 2. Description of Related Art

For the application of components in the computer devices, alloy sputtering target material formed of an alloy of iron, cobalt, chromium and boron can be applied to a soft magnetic layer of a hard disk drive (HDD). The thickness of the soft magnetic layer is almost the sum of the thicknesses of other film layers and hence has the largest demand for the target material. In the process of alloy sputtering targets, sputtering is a physical vapor deposition technique, which deposits a desired target material on a surface of a target object to form a thin film of the target material. During the sputtering process, the quality of the target material often determines the quality of the sputtering result.

In recent years, the manufacture of a target material has evolved from a vacuum induction melting (VIM) process and has now been replaced by conventional powder metallurgy (PM). The target material manufactured by the PM process has fine grains, which can improve the performance of the sputtered film Therefore, current sputtered target materials are generally manufactured through a PM process. However, during the manufacturing process, the target material needs to be rapidly cooled, which may lead to a non-uniform or insufficiently fine distribution of microstructure of the target material and thus result in a poor quality of the target material.

Therefore, how to overcome the above-described drawbacks has become critical.

### SUMMARY

In view of the above-described drawbacks, the present disclosure provides a method for manufacturing a target material, which comprises the steps of: mounting a substrate; disposing raw material powder on the substrate and melting the raw material powder by laser to form a target material layer; disposing new raw material powder on the target material layer and melting the new raw material powder by laser to form another target material layer, and repeating the preceding process to cause the target material layers to form a target material column; cooling the target material column; removing the target material column from the substrate; and performing vacuum heat treatment on the target material column.

In an embodiment, the step of disposing the raw material powder on the substrate and melting the raw material powder by laser to form the target material layer further comprises: laying the raw material powder flat on the substrate with a scraper to form a powder layer; and according to a planar size of the target material, melting the raw material powder of the powder layer by laser to form the target material layer.

In an embodiment, the step of forming said another target material layer further comprises: forming another powder layer on the substrate and the target material layer; and according to a planar size of the target material, melting the raw material powder of said another powder layer by laser to form said another target material layer.

In an embodiment, the raw material powder comprises iron, cobalt, chromium and boron.

In an embodiment, before disposing the raw material powder on the substrate, the method further comprises the steps of: coarsely screening the raw material powder through a coarse screen to obtain the raw material powder having a fine size; and finely screening the raw material powder having the fine size through a fine screen to obtain the raw material powder having a particle size of about 20 to 70 micrometer (μm) and a powder flowability (Can Index) less than 16%.

In an embodiment, the laser has a power of 140 W and a scanning speed of 900 mm/s.

In another embodiment, the substrate is mounted in a construction cabin, and the steps of disposing the raw material powder on the substrate, melting the raw material powder by laser and cooling the target material column are performed in the construction cabin.

In the above-described embodiment, the construction cabin is filled with inert gas or nitrogen.

In another embodiment, before performing the step of mounting the substrate, the method further comprises surface grinding the substrate.

In another embodiment, the step of performing vacuum heat treatment on the target material column further comprises: transporting the target material column into a mold of a vacuum heat treatment furnace; pressurizing and fastening the target material column in the mold; vacuumizing the vacuum heat treatment furnace and then filling it with inert gas, and performing heating and pressurizing process to the vacuum heat treatment furnace; after completing the heating and pressurizing process, cooling the vacuum heat treatment furnace to 25° C. to 40° C.; removing the pressure applied on the target material column; and taking out the target material column subjected to the vacuum heat treatment from the vacuum heat treatment furnace.

According to embodiments of the present disclosure, raw material powder is disposed on a substrate and melted by laser to form a target material layer, and the preceding step is repeated so as to cause a plurality of target material layers to form a target material column. After the target material column is cooled, it is removed from the substrate and subjected to vacuum heat treatment. Therefore, the required target material column is additively manufactured. Further, the target material is subjected to post-treatment, i.e., vacuum heat treatment so as to have a finer and more uniform microstructure, thereby providing a preferred film characteristic and a higher sputtering efficiency for users and facilitating to control the quality of hard disks if the target material is applied in the hard disks.

### BRIEF DESCRIPTION OF DRAWINGS

FIG. 1 is a schematic flow diagram showing a method for manufacturing a target material according to the present disclosure;

FIGS. 2A to 2E are schematic diagrams showing the steps of forming a target material column according to the present disclosure;

FIGS. 3A to 3C are schematic diagrams showing the steps of performing vacuum heat treatment according to the present disclosure; and

FIG. 4 illustrates photographs showing microstructure of a target material column with and without vacuum heat treatment.

### DETAILED DESCRIPTION

The following illustrative embodiments are provided to illustrate the disclosure of the present disclosure, these and other advantages and effects can be apparent to those in the art after reading this specification.

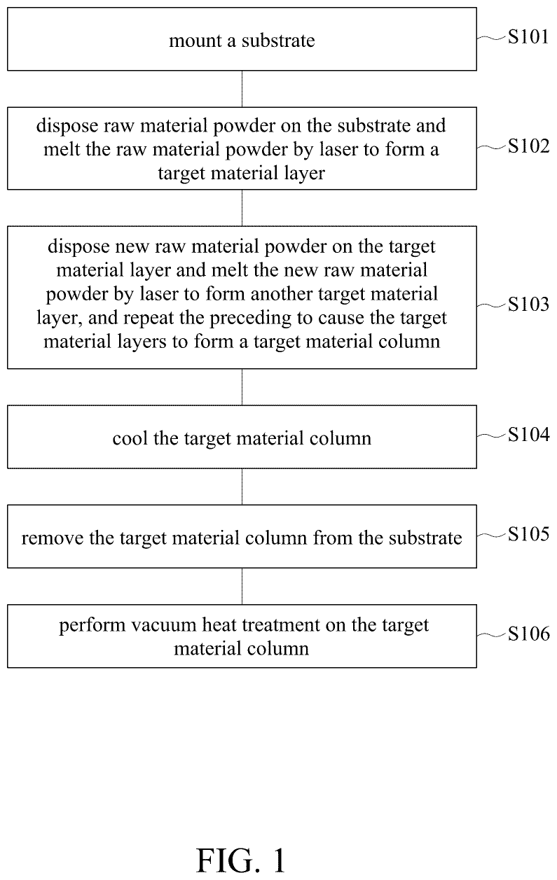

FIG. 1 is a schematic flow diagram showing a method for manufacturing a target material according to the present disclosure. In particular, the method can be performed on a computer device or by a processing device having a computer device. That is, a control command sent from a computer device based on set parameters causes a processing element such as a scraper or laser to perform a corresponding operation.

First, at step S101, a substrate is mounted. Specifically, the substrate is fastened at a processing place. In an embodiment, the substrate is a metal substrate, which provides a processing area where a target material is to be formed gradually.

At step S102, raw material powder is disposed on the substrate and melted by laser to form a target material layer. Simply put, the raw material powder is disposed on the substrate and then melted by laser, such that the raw material powder melted by laser forms the target material layer. In particular, the raw material powder is laid flat on the substrate and melted by laser according to a planar size of the target material. The planar size of the target material is the size of a top-view plane of the target material. For example, if the target material is in the shape of a rectangular cake, the planar size is the area calculated based on the perimeter or length and width of the target material. In another embodiment, if the target material is in the shape of a round cake, the planar size is the area calculated according to the diameter (or radius) of the target material. Through the above-described process, the raw material powder is melted by laser into the target material layer.

In an embodiment, the step of forming the target material layer includes the following steps: laying the raw material powder flat on the substrate by a scraper to form a powder layer, and according to a planar size of the target material, melting the raw material powder of the powder layer by laser to form the target material layer. Briefly, to ensure that the target material layer formed each time has the same height, the scraper is used to lay the raw material powder flat on the substrate to form the powder layer. Then, considering the plane size of the target material, the raw powder material of the powder layer is melted by laser to form the target material layer.

In an embodiment, the raw material powder is a mixture of iron powder, cobalt powder, chromium powder and boron powder.

At step S103, new raw material powder is disposed on the target material layer and melted by laser to form another target material layer. The above-described process is repeated to cause the target material layers to form a target material column. Briefly, to reach a desired height of the garget material, the process of providing the raw material powder and melting the raw material powder by laser is repeated in this step. That is, new raw material powder is continuously provided on the substrate and on the melted raw material powder and melted by laser according to the planar size of the target material, thereby forming a new target material layer. As such, a plurality of target material layers form a target material column.

In an embodiment, another target material layer is formed according to the following steps: forming another powder layer on the substrate and the target material layer, and melting the raw material power of said another powder layer by laser according to the planar size of the target material. Briefly, to form another target material layer on the target material layer formed at step S102, another powder layer (i.e., new raw material powder) is formed on the target material layer. Similarly, considering the planar size of the target material, the raw material power of said another powder layer is melted by laser to form another target material layer.

At step S104, the target material column is cooled. Preferably, the target material column is rapidly cooled and therefore rapidly solidified.

At step S105, the target material column is removed from the substrate. In an embodiment, the target material column can be removed from the substrate by wire cutting.

At step S106, vacuum heat treatment is performed on the target material column. In this step, the vacuum heat treatment is performed on the target material column which is obtained from the substrate. To make the quality of the target material column more stable, the present disclosure disposes the target material column in a vacuum heat treatment furnace for vacuum heat treatment. As such, the microstructure of the target material has a more uniform and finer distribution.

The vacuum heat treatment can include the following steps: transporting the target material column into a mold of the vacuum heat treatment furnace; lowering a hydraulic rod to pressurize and fasten the target material column in the mold; vacuumizing the vacuum heat treatment furnace and then filling it with inert gas, and performing heating and pressurizing process to the vacuum heat treatment furnace; after completing the heating and pressurizing process, cooling the vacuum heat treatment furnace to room temperature; after removing the pressure applied on the target material column, taking out the target material column subjected to the vacuum heat treatment from the vacuum heat treatment furnace. After the vacuum heat treatment, the microstructure of the target material column has a more uniform and finer distribution.

In an embodiment, before being laid on the substrate, the raw material powder is screened according to the size. In particular, the raw material powder is coarsely screened through a coarse screen to obtain the raw material powder having a fine size. Then, the raw material powder having the fine size is finely screened through a fine screen to obtain the raw material powder having a desired particle size. Preferably, the obtained raw material powder has a particle size of about 20 to 70 μm and a powder flowability (Can Index) less than 16%. The powder flowability refers to the Can index, which indicates the compressibility of the powder. Specifically, a cyclone powder classifier can be used to screen out the powder having a too small particle size by a centrifugal force, thereby ensuring the processing quality of subsequent processes.

In another embodiment, before being mounted, the substrate is pre-processed, including surface grinding the substrate and cleaning the ground surface of the substrate with a scraper. Briefly, to form a target material layer having a uniform height and thickness, before mounting the substrate, the surface of the substrate is ground so as to be flat and clean without debris or leftovers from previous use.

In a further embodiment, the substrate is mounted in a construction cabin, and thus the steps of disposing the raw material powder on the substrate, melting the raw material powder by laser and cooling the target material column are performed in the construction cabin. Further, the construction cabin is filled with inert gas or nitrogen so as to maintain environmental conditions for manufacturing the target material and reduce the impact of external environment.

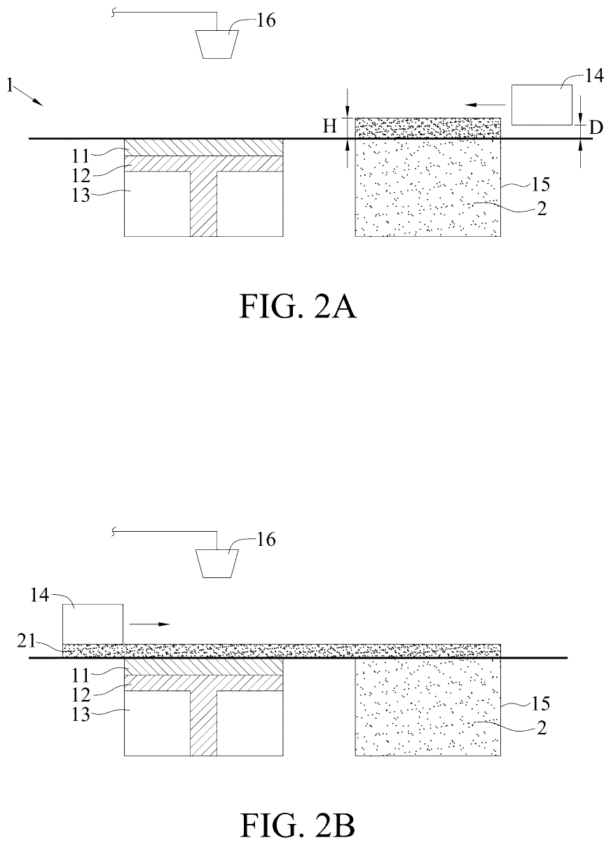

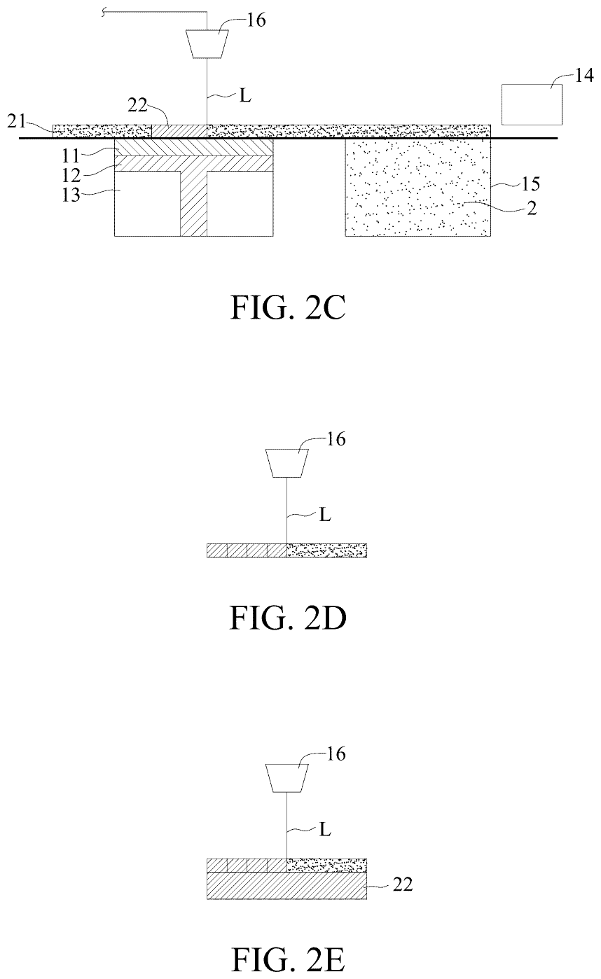

FIGS. 2A to 2E are schematic diagrams showing the steps of forming a target material column according to the present disclosure. According to the present disclosure, a substrate 11 is mounted and fastened on a processing platform 1 for processing and manufacturing a target material, and raw material powder 2 is disposed on the substrate 11 and melted by laser 16. Referring to FIG. 2A, the processing platform 1 has a substrate carrier 12 located in a processing groove 13 and capable of ascending and descending in the processing groove 13. The substrate 11 can be fastened on the substrate carrier 12. The substrate carrier 12 can drive the substrate 11 to ascend or descend in the processing groove 13 according to settings during the process for manufacturing the target material. To mount the substrate 11, the substrate 11 is first secured on the substrate carrier 12, and then a gap D between the substrate 11 and a scraper 14 and a levelness of the substrate 11 are corrected using a thickness gauge so as to avoid a subsequent occurrence of non-uniform laying of the powder. After being mounted on the processing platform 1, the substrate 11 can be lowered into the processing groove 13 with the surface of the substrate 11 being flush with the opening of the processing groove 13.

In an embodiment, before mounting the substrate 11, pre-processing can be performed. First, the substrate 11 is prepared and surface ground. If the substrate 11 has performed a target material manufacturing process, the previously printed target material product on the substrate 11 is removed first and then upper and lower surfaces of the substrate are ground by using a surface grinder so as to have preferred planarity and parallelism, thereby reducing variables in subsequent printing production. Then, the processing platform 1 is cleaned. That is, the raw material powder left in the previous target material manufacturing process can be removed using an anti-static brush, and the processing platform 1 can be cleaned using a wiping paper with anhydrous alcohol.

Further, the scraper 14 can be cleaned or replaced. When the scraper 14 is cleaned, the surface of the scraper 14 can be cleaned with anhydrous alcohol, thus preventing the raw material powder from remaining on the contact surface of the scraper 14 that otherwise may result in an uneven surface of the scraper 14. On the other hand, when the scraper 14 is replaced, the scraper 14 is removed from the processing platform 1 first and then the raw material powder attached to the surface of the scraper 14 is removed with a brush. After an upper base (not shown) for mounting the scraper 14 and the scraper 14 are removed from the processing platform 1, they are cleaned with anhydrous alcohol so as to prevent the raw material powder from remaining on the contact surface of the scraper 14 that otherwise may result in an uneven surface of the scraper 14.

Referring to FIGS. 2A and 2B, the scraper 14 is mounted on the processing platform 1 and movable freely in left and right directions (shown as a left arrow direction of FIG. 2A and a right arrow direction of FIG. 2B). The gap D between the scraper 14 and the surface of the substrate 11 serves as a thickness of a powder layer 21 to be formed. That is, the scraper 14 and the surface of the substrate 11 are kept parallel to each other with the gap D therebetween.

In an embodiment, the processing platform 1 may be provided with a recessed powder feeding tank 15 disposed adjacent to the processing groove 13 for storing the raw material powder 2. To provide the raw material powder 2, the powder feeding tank 15 lifts up the raw material powder 2 stored therein and thus the raw material powder 2 in an upper portion of the powder feeding tank 15 is exposed from the powder feeding tank 15 with a height H (which is greater than the gap D). To lay the raw material powder 2, the scraper 14 successively takes out the raw material powder 2 from the powder feeding tank 15 that is sufficient to be laid flat on the substrate 11 to form the powder layer 21. When the scraper 14 moves in the left direction (as shown in the arrow direction of FIG. 2A), the raw material powder 2 exposed from the powder feeding tank 15 is scraped toward the substrate 11 and flattened on the substrate 11 through the movement of the scraper 14. As such, the raw material powder 2 is laid flat on the substrate 11 to form the powder layer 21.

Further, before providing the raw material powder 2, the raw material powder 2 can be screened to obtain preferred raw material powder 2, thus improving the quality of the target material. The present disclosure uses a vibrating screen device to screen the raw material powder 2. The screening of the raw material powder 2 can be divided into coarse screening and fine screening.

In a coarse screening process, the raw material powder is coarsely screened through a coarse screen to obtain the raw material powder 2 having a fine size. In particular, a mechanically vibrating screen is used to screen out the raw material powder having an excessive particle size (such as a particle size greater than 70 μm). Further, if the raw material powder has lumped, the lumped raw material powder is broken into pieces for coarse screening. Briefly, the initial raw material powder 2 may include lumped, granular or large particle size of powder, which is screened out by using a screen having a size less than the aforementioned large particle size so as to keep the raw material powder 2 having the fine size. Furthermore, in a fine screening process, the raw material powder 2 having the fine size is finely screened through a fine screen to obtain the raw material powder 2 having a particle size of about 20 to 70 μm and a powder flowability (Carr Index) less than 16%. For example, a cyclone powder classifier can be used to screen out the powder having a too small particle size by a centrifugal force, thereby ensuring the processing quality of subsequent processes.

Referring to FIG. 2C, the laser 16 can be mounted on the processing platform 1. Under control of the processing platform 1, the laser 16 can emit laser light L toward the raw material powder on the substrate 11 and scan the raw material powder 2 according to the settings so as to melt and sinter the scanned raw material powder 2. In particular, referring to FIG. 2D, the laser light L can scan the raw material powder 2 line by line to melt and sinter the raw material powder 2. As such, after the scanning operation, a target material layer 22 is formed in the powder layer 21. In an embodiment, the laser 16 can have a power of 140 W and a scanning speed of 900 mm/s.

To achieve an additive result, new raw material powder 2 can be laid on the target material layer 22 and melted by the laser 16. Referring to FIG. 2E, another powder layer is scanned by the laser light L line by line to form another target material layer on the target material layer 22. As such, a desired height of the target material is achieved by stacking a plurality of target material layers. In particular, the target material layer 22 can be obtained after the steps of providing raw material powder to form a powder layer and melting the powder layer by laser are performed. To perform the next steps of powder laying and melting, the substrate carrier 12 of the processing platform 1 must first be lowered by a distance of height D to cause the surface of the target material layer 22 to be flush with the opening of the processing groove 13. Then, the steps of forming another powder layer and melting the powder layer by laser are performed to obtain another target material layer stacked on the target material layer 22.

It should be noted that more raw material powder 2 is exposed upward from the powder feeding tank 15 to perform the steps of providing and laser melting raw material powder for another time. As such, after the steps of powder laying and melting are performed a plurality of times, the stacking height of the plurality of target material layers 22 reaches the desired height of the target material. That is, a target material column served as a target material is formed. For example, if the desired thickness of the target material is 5 cm and the thickness of the target material layer 22 formed each time by performing the steps of providing and laser melting raw material power is 5 mm, it is necessary to perform the step of providing and laser melting raw material powder ten times.

Then, the target material column is cooled. Preferably, the target material column can be rapidly cooled and therefore rapidly solidified. In particular, the target material column is cooled with a high cooling rate of 106° C./sec so as to be rapidly solidified. Further, the cooling rate can be controlled through parameters such as the laser scanning rate. That is, the laser parameters are optimized to determine the optimal cooling rate for refining target material grains and avoiding boron precipitation.

Specifically, the target material formed in the present disclosure can be used for hard disk sputtering. In an embodiment, the processing platform 1 can include a construction cabin (not shown) for providing a processing environment. The construction cabin is closed and filled with inert gas or nitrogen, and has a door for users to operate. The substrate 11 is mounted in the construction cabin, and the steps of providing and melting raw material powder and cooling the target material are all performed in the construction cabin. Therefore, the method for manufacturing the target material according to the present disclosure can be performed automatically through the processing platform 1 with the construction cabin.

Further, after mounting the substrate 11 and adding sufficient raw material powder 2 in the powder feeding tank 15, the door of the construction cabin is closed. That is, after hardware settings (such as mounting the substrate and adding the raw material powder) have been completed, the door of the construction cabin is closed first and then nitrogen is input and the substrate 11 is heated. When the set condition (e.g., 150° C.) is reached, the preparation for printing (i.e., manufacture the target material) at any time is completed. In an embodiment, the processing platform 1 is a computer device to which the set parameters are input for automatic control. That is, the parameters (such as the laser power, scanning speed, etc.) required for manufacturing the target material according to an embodiment of the present disclosure can be input by users.

Then, a pattern is prepared. A 3D (three dimensions) geometric pattern of the product is completed by using a drawing software and then imported into a software corresponding to the computer device of the processing platform 1 for subsequent settings. Finally, software settings are performed. After the pattern is prepared and imported into the computer device of the processing platform 1, the position of the substrate needs to be determined and the printing parameters including such as the thickness of the powder layer, the temperature of the substrate, the power of the laser, and the scanning rate need to be set. In an embodiment, an SLM (Selective Laser Melting) device is used to set the above parameters and perform the above steps.

In addition, by performing vacuum heat treatment on the target material column, the microstructure of the target material column has a more uniform and finer distribution.

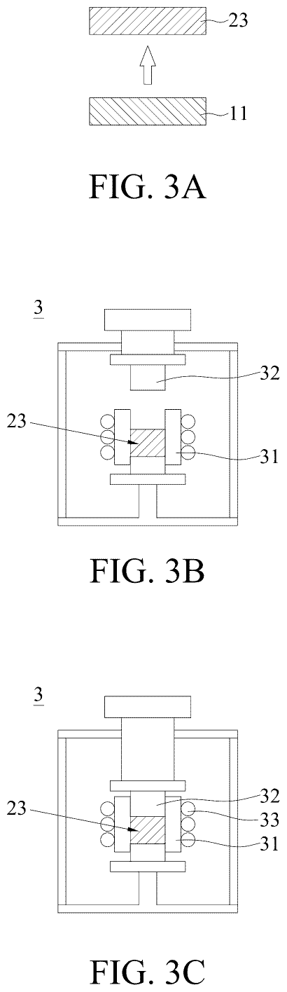

FIGS. 3A to 3C are schematic diagrams showing the steps of performing vacuum heat treatment according to the present disclosure. Referring to FIG. 3A, the target material column 23 formed of a plurality of target material layers and additively manufactured can be removed from the substrate 11. Next, the target material column 23 is put into a vacuum heat treatment furnace 3 for vacuum heat treatment. Referring to FIG. 3B, the target material column 23 is disposed in a mold 31 of the vacuum heat treatment furnace 3 for pressurization. Further, referring to FIG. 3C, a hydraulic rod 32 of the vacuum heat treatment furnace 3 is lowered to pressurize and fasten the target material column 23 in the mold 31. At this point, the vacuum heat treatment furnace 3 is vacuumized and then filled with inert gas. Next, the heating and pressuring process are performed in the vacuum heat treatment furnace 3 to cause the target material 23 in the mold 31 to be heated and pressurized (e.g., through a heating pipe 33). Once the heating and pressurizing process is completed, the vacuum heat treatment of the target material column 23 is completed. Thereafter, the vacuum heat treatment furnace 3 is cooled to room temperature, and then the pressure is removed. Next, the target material column 23 can be taken out from the vacuum heat treatment furnace 3.

Specifically, after the additive manufacturing of the target material column 23 is completed, the target material column 23 is taken out from the construction cabin of the SLM device. Then, the substrate 11 is removed by wire cutting, thus obtaining the multi-piece integrated target material column 23. Thereafter, the target material column 23 is transported into the vacuum heat treatment furnace 3 and disposed in the mold 31, and the hydraulic rod 32 is lowered to pressurize and fasten the target material column 23. Thereafter, the door of the furnace is closed, and the furnace is vacuumized and then filled with inert gas. When oxygen content in the furnace decreases to 0.1% (i.e., 1000 ppm), the furnace is heated and pressurized. When the temperature reaches 900° C. to 1100° C. and the pressure reaches 250 bar to 350 bar, the pressure and temperature are maintained for about 2-4 hr to complete the heating and pressurizing process. Thereafter, the heating source is closed and the furnace is cooled to the room temperature such as 25° C. to 40° C. through air cooling. Finally, the pressure is removed and the target material column 23 is taken out from the vacuum heat treatment furnace 3.

The present disclosure can be applied to processing of a sputtered target material of FeCoCrB alloy. In particular, it is a method for manufacturing a FeCoCrB target material in combination with additive manufacturing and post-treatment. In the additive manufacturing, the raw material powder having an appropriate particle size is obtained by using a screening machine. Then, appropriate parameters are selected and a processing platform is used to process the raw material powder into a target material layer. After the repeated steps of powder laying, melting and so on, a multi-piece integrated target material column is formed. Thereafter, the substrate is removed and the target material column is subjected to vacuum heat treatment. Therefore, the present disclosure uses a unique process of rapid solidification after melting the raw material powder to manufacture the target material, thereby effectively improving the density of the target material and reducing the precipitation phase of boride. Briefly, through the laser, additive manufacturing and rapid solidification process (RSP), the present disclosure improves the alloy adding ability and fines the microstructure. Then, the FeCoCrB ultrafine grain microstructure used for a hard disk target material is subjected to hot isostatic pressing (HIP) or hot pressing (HP) to adjust the quality thereof. As such, the boride precipitate in the base phase is finer and more uniform, thereby obtaining a preferred sputtered film characteristic.

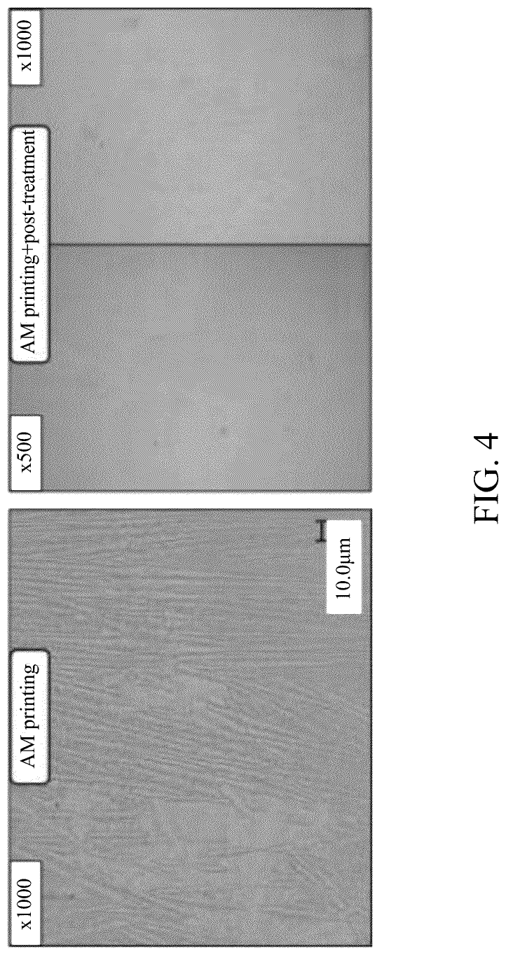

FIG. 4 are photographs showing the microstructure of a target material column with and without vacuum heat treatment. On the left is a microstructural photograph taken by an SEM electron microscope with 1000× magnification after additive manufacturing (AM), and on the right is a microstructural photograph taken by an SEM electron microscope with 500× and 1000× magnifications after additive manufacturing (AM) and vacuum heat treatment. As shown in FIG. 4, the microstructure on the right is more uniform and finer than that on the left.

Compared with the conventional powder metallurgy process, the present disclosure causes the microstructure of the target material to be finer, more uniform and compact, improves the quality of the target material to form a sputtered film with preferred performance, and maximizes the service life of the target material. Further, by taking advantages of additive manufacturing and one net shape forming processes, the present disclosure can reduce loss in material column-processing and decrease production procedures. Also, the present disclosure can commercialize mass production of the target material in a single batch. Therefore, compared with the conventional powder metallurgy process, the present disclosure can greatly reduce the manufacturing cost. Meanwhile, the microstructure of the finished product (target material) after vacuum heat treatment can be more uniform and finer.

Therefore, the present disclosure provides a method for manufacturing a target material, which uses additive manufacturing to melt powder by laser at a high temperature and rapidly solidifies the powder and performs vacuum heat treatment on the target material after the additive manufacturing is completed. As such, the target material has a finer and more uniform microstructure for use in a hard disk, thereby providing a preferred film characteristic and a higher sputtering efficiency for users. For example, during manufacturing of a hard disk, it facilitates to control the quality of the hard disk. In addition, the above-described processing devices are only illustrative and not intended to limit the present disclosure.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. A method for manufacturing a target material, comprising the steps of:
mounting a substrate;
disposing raw material powder on the substrate and melting the raw material powder by laser to form a target material layer;
disposing new raw material powder on the target material layer and melting the new raw material powder by laser to form another target material layer, and repeating the preceding process to cause the target material layers to form a target material column;
cooling the target material column;
removing the target material column from the substrate; and
performing vacuum heat treatment on the target material column.

2. The method of claim 1, wherein the step of disposing the raw material powder on the substrate and melting the raw material powder by laser to form the target material layer further comprises:
laying the raw material powder flat on the substrate with a scraper to form a powder layer; and
according to a planar size of the target material, melting the raw material powder of the powder layer by laser to form the target material layer.

3. The method of claim 1, wherein the step of forming said another target material layer further comprises:
forming another powder layer on the substrate and the target material layer; and
according to a planar size of the target material, melting the raw material powder of said another powder layer by laser to form said another target material layer.

4. The method of claim 1, wherein the raw material powder comprises iron, cobalt, chromium and boron.

5. The method of claim 1, before disposing the raw material powder on the substrate, further comprising the steps of:
coarsely screening the raw material powder through a coarse screen to obtain the raw material powder having a fine size; and
finely screening the raw material powder having the fine size through a fine screen to obtain the raw material powder having a particle size of about 20 to 70 micrometer (μm) and a powder flowability (Carr Index) less than 16%.

6. The method of claim 1, wherein the laser has a power of 140 W and a scanning speed of 900 mm/s.

7. The method of claim 1, wherein the substrate is mounted in a construction cabin, and the steps of disposing the raw material powder on the substrate, melting the raw material powder by laser and cooling the target material column are performed in the construction cabin.

8. The method of claim 7, wherein the construction cabin is filled with inert gas or nitrogen.

9. The method of claim 1, before performing the step of mounting the substrate, further comprising surface grinding the substrate.

10. The method of claim 1, wherein the step of performing vacuum heat treatment on the target material column further comprises:
transporting the target material column into a mold of a vacuum heat treatment furnace;
pressurizing and fastening the target material column in the mold;
vacuumizing the vacuum heat treatment furnace and then filling it with inert gas, and performing heating and pressurizing process to the vacuum heat treatment furnace;
after completing heating and pressurizing process, cooling the vacuum heat treatment furnace to 25° C. to 40° C.;
removing the pressure applied on the target material column; and
taking out the target material column subjected to the vacuum heat treatment from the vacuum heat treatment furnace.
